(19) United States
(12) Patent Application Publication
(10) Pub. No.: US 2010/0156408 A1
(43) Pub. Date: Jun. 24, 2010

(54) DC magnetic field interceptor apparatus and method

(75) Inventors: Richard J. McClure, San Diego, CA (US); Peter V. Czipott, San Diego, CA (US); R. Kemp Massengill, Leucadia, CA (US)

Correspondence Address: GERALD W. SPINKS, 546 WESTBURY LANE, GEORGETOWN, TX, 78633, US

(73) Assignees: Intercept Logic, Inc., Escondido, CA (US); Quantum Magnetics, Inc., San Diego, CA (US)

(21) Appl. No.: 12/653,738

(22) Filed: Dec. 17, 2009

Related U.S. Application Data
(60) Provisional application No. 61/203,487, filed on Dec. 22, 2008.
(60) Provisional application No. 61/204,006, filed on Dec. 31, 2008.

(51) Int. Cl. G01R 33/02

(52) U.S. Cl. 324/259

(57) ABSTRACT

A hand held apparatus and method for detecting paper currency, within a package, where the paper currency has a ferromagnetic component. The apparatus includes a DC magnetic field source for inducing a DC de-magnetization field in any ferromagnetic paper currency that may be present within a package, and DC magnetic sensors for detecting certain characteristic patterns in the DC “de-mag” field induced by the DC magnetic field source. These certain characteristic field patterns are indicative of paper currency arranged in commonly found arrangements.

### CROSS REFERENCE TO RELATED APPLICATIONS

This application relies upon U.S. Provisional Patent Application No. 61/203,487, filed on Dec. 22, 2008, and entitled “Hand-Directed Cash Interceptor Apparatus and Method,” and upon U.S. Provisional Patent Application No. 61/204,006, filed on Dec. 31, 2008, and entitled “Hand-Directed Cash Interceptor Apparatus and Method,”

### STATEMENT REGARDING FEDERALLY SPONSORED RESEARCH OR DEVELOPMENT

Not Applicable

### BACKGROUND OF THE INVENTION

1. Field of the Invention

This invention is in the field of methods and apparatus used in the detection of illicit shipments of paper currency.

2. Background Art

The detection of paper currency in apparently innocent packages can be a major tool in crime prevention or intervention. For example, hundreds of billions of dollars each year are illegally sent in and out of the United States, with most of this money funding illicit drug activities and/or terrorism. Most of this currency is surreptitiously sent via the United States Post Office, FedEx, UPS, and DHL, although some is hand-carried across borders, or stashed away in checked baggage. The problem of illegal currency trafficking is not confined to the United States, as most countries have a similar problem. The financing for illegal drug activity, for instance, comes mainly from illegal currency transportation. Finding this illegal currency is a major dilemma. In the United States, the difficulty is compounded, as the use of x-ray scanning technology for United States mail is considered an invasion of privacy.

### BRIEF SUMMARY OF THE INVENTION

The present invention provides an apparatus and method for finding paper currency inside a package. The functionality of the invention is based on the fact that modern American currency, and that of many other countries as well, incorporates at least some ferromagnetic material. The present invention consists of a scanning tool that incorporates a DC magnetic source, one or more DC magnetometer sensors, and the necessary electronic analysis equipment to process and analyze signals from the sensors. The sensors can be arranged as gradiometers. The sensors must be capable of sensing the presence of a DC magnetic field. Examples are magneto-resistive sensors, fluxgate sensors, Hall effect sensors, or optical sensors. The magnetic source can be a permanent magnet, a ceramic magnet, a flexible rubber magnet, or one or more DC electromagnetic coils, or some other source of a DC magnetic field. The magnetic source must be large enough to establish a magnetic field that will penetrate well into the interior of a desired package size, with the desired package size being determined by the type of packages that are being subjected to screening in a particular application. This magnetic field establishes a secondary magnetic field, commonly referred to as a “de-mag” field, in the ferromagnetic components or portions of the paper currency. Ferromagnetic paper currency that is neatly stacked will have a de-mag field that has a first type of characteristic signal having a uniform and repetitive periodicity that can be thought of as a “bump-bump-bump” signal, either represented as an audible signal or a visible graph. Conversely, ferromagnetic paper currency that is arranged in a disorganized pile will have a de-mag field that has a second type of characteristic signal having a uniform but non-repetitive signal spread over the entire area of the currency pile.

The scanning tool is positioned relative to one or more sides of the package, so that the DC magnetizing field creates a DC de-mag field in the currency, regardless of how the currency is arranged. This de-mag field can be detected by the magnetic sensor or sensors. Electronic computation equipment on or associated with the scanning tool analyzes the signals produced by the magnetic sensors to detect the existence of either the periodic uniform field or the non-periodic uniform field discussed above, and to indicate that ferromagnetic paper currency is probably present, in either case.

The novel features of this invention, as well as the invention itself, will be best understood from the attached drawings, taken along with the following description, in which similar reference characters refer to similar parts, and in which:

### BRIEF DESCRIPTION OF THE SEVERAL VIEWS OF THE DRAWINGS

FIG. 1 is a schematic representation of the apparatus of the present invention;

FIG. 2 is a schematic representation of the magnetizing field generated by the apparatus;

FIG. 3 is a schematic representation of the demag field generated and detected by the apparatus;

FIG. 4 is a schematic of a layout of two sets of sensors arranged as gradiometer pairs;

FIG. 5 is a graphical and schematic representation of the signal pattern generated by neat stacks of paper currency, with the present invention;

FIG. 6 is a graphical representation of the signal pattern generated by a loose pile of paper currency, with the present invention; and

FIG. 7 is a graphical and schematic representation of the signal pattern generated by several stacks and a pile of paper currency, with the present invention.

### DETAILED DESCRIPTION OF THE INVENTION

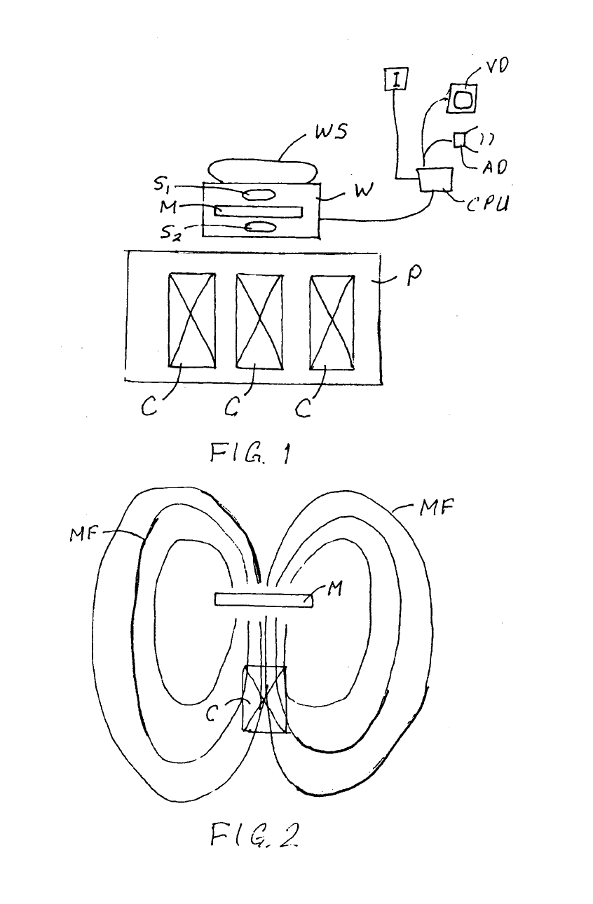

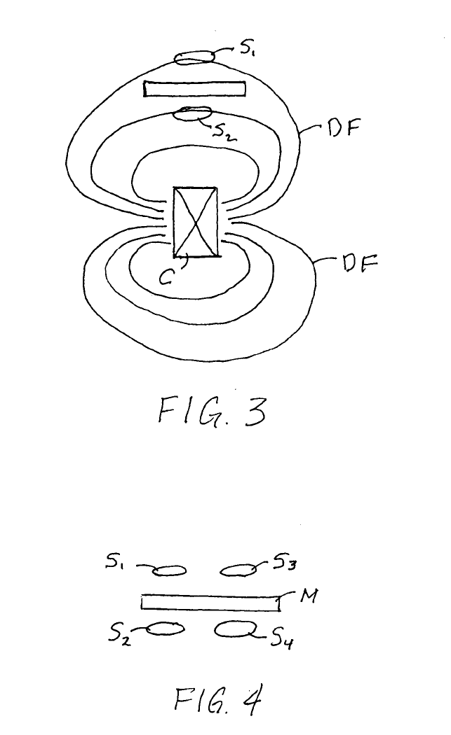

As shown in FIG. 1, a first embodiment of a hand-directed scanning tool, in this case a hand-held wand W, is employed to search for paper currency hidden within a box or package P. This embodiment of the hand-held scanning tool W has a strap WS in which the operator's hand is placed. A DC magnetizing source M mounted on the wand W produces a magnetic field MF, as shown in FIG. 2, which induces magnetization in the hidden currency C. As shown in FIG. 3, the de-magnetization or “de-mag” field DF from this currency is detected, for example, by the magneto-resistive sensors S₁, S₂ of the invention, triggering an alarm, preferably with both a visual display VD and an audio display AD. Signal processing and analysis can be performed on the wand W or in an associated computer CPU.

The hand-held wand W could incorporate a handle rather than a strap, without departing from the spirit of the invention. Boxes and packages are screened for paper currency by positioning the hand-directed scanning tool W as close to the surface of the box or package as possible, sequentially scanning one or more sides, and preferably all sides, of the package.

In addition to the elements discussed above, the present invention can include any type of alarm or interconnection that may be appropriate for a given application, and a protective casing. If desired, appropriate readout screens can be provided to show outputs of the sensors or the analysis circuitry, as well as hard-copy printouts of the sensor outputs or the analysis circuitry outputs. These are under computerized direction, either from the circuitry on the scanning tool W or from the associated computer. Also, if desired, the alarm indices can be connected to the Internet I, which allows distant monitoring of alarm events. In addition, expert systems and artificial intelligence can be employed to process the garnered information, including, but not limited to, neural nets and rule-based systems.

United States currency has little inherent magnetization, typically less than 1 Gauss. Sensor systems which use only an available ambient magnetic field, such as the Earth's field of approximately 0.5 Gauss, cannot detect currency at any distance within packages because of this lack of inherent magnetization in the currency. So, providing an independent magnetic field is required to pre-magnetize the bills to allow detection by the sensor system.

As discussed above, the magnetization source M is utilized to induce magnetization in the currency, with the preferred embodiment of the magnetizing source M being a DC permanent magnet. In order to scan packages measuring up to about 8 inches on a side, for example, the magnetizing source M can be a flat neodymium/iron/boron magnet preferably measuring 3 inches by 4 inches, or 4 inches by 6 inches and ¼ inch to ¾ inch in thickness. The paper currency interceptor system of the present invention must be able to provide a magnetic field which penetrates as deeply as possible into a package of the desired size, so as large a magnetic source as possible is employed, without being overly heavy for the particular application. During use, a magnetization source M which has this relatively thin, flat shape is preferably oriented with its face being parallel to the surface of the box or package being scanned. This orientation allows the deepest penetration of the magnetic field, from a source having this shape, into the box or package.

Alternatively, other DC magnetizing sources can be employed. A few examples are ceramic magnets, flexible-rubber magnets, and electromagnetic coils producing a DC magnetic field.

Safety concerns must always be considered whenever humans are exposed to magnetic fields. Having a relatively broad, relatively thin permanent magnet source, as described herein, produces a smaller, and therefore safer, field at the surface of the wand than would be the case with a relatively thick magnet of relatively limited breadth. At the same time, for a given thickness, a broader permanent magnet source produces a greater field at a given distance than one which is less broad. When stronger magnetization sources are used, the paper currency interceptor of the present invention should be used with caution on human beings who have pacemakers.

Associated with the magnetizing element M is the sensor system S of the present invention, which detects the “demag” magnetic field DF emanating from the magnetized currency as the wand W is positioned near the surface of the box or package.

A single magneto-resistive sensor S can be employed, or, alternatively, an array of magneto-resistive sensors could be used, without employing gradiometer formatting. However, spurious signals from an unrelated distant source can cause annoying false alarms. To provide common-mode rejection of these distant unwanted signals, the sensor elements are preferably arranged in a gradiometer format, consisting of one or more sensor gradiometer pairs. One such embodiment is the configuration shown in FIG. 4, utilizing 2 sensor gradiometer pairs. In this embodiment, sensors S1 and S2 form a gradiometer pair; and sensors S3 and S4 form a gradiometer pair. In the preferred embodiment, however, only one gradiometer pair, consisting of sensors S1 and S2, is utilized, as shown in FIG. 3. Of course, if desired, three or more gradiometer pairs can be utilized. The use of a gradiometer format greatly improves reliability, as it rejects magnetic signals from extraneous irrelevant sources. It is desirable to have the sensors constituting a gradiometer pair spaced as widely as possible, such as 3 to 4 inches apart, as this increases detectability at a distance within the package. The output of the sensors S can be sent to a computer located either on the wand W or separately, and computer analysis can be employed for processing data.

The sensor system S and the DC magnetization source M of the present invention are rigidly secured to the wand W, in a fixed spatial relationship relative to each other, so that unwanted false-alarm signaling does not result from relative movement between the sensors and the magnetization source. The sensors are also shielded from temperature variations which could cause faulty and inaccurate sensing. In addition to a thermal-insulating protective cover, or as an alternative, the sensor assemblies can be coated liberally with epoxy or another suitable insulating material.

The electronics circuitry of the present invention features low-noise amplifiers, and gold contacts, rather than tin, should be used for increased reliability. Signal digitization places the operation and the data collection under computerized control, which allows for special noise-cancelling techniques and excellent flexibility for signal-display options. The preferred embodiment powers the electronics circuitry with an AC/DC step-down transformer, for reliability. However, the electronics can be powered with a battery-pack, for convenience.

In the preferred embodiment, the present invention has an alarm with both audio components and visual components. Numerous options can be utilized, including, but not limited to, a multi-tone audio alarm, colored lights (such as green for no detected signal, and red for an alarm), a visual display of signal strength, and other desired graphic and visual displays. Also, if desired, Internet connectivity can be employed for transmitting information to a remote location, and even for remote real-time monitoring of alarm events as they occur. Expert artificial intelligence systems can be employed for automated data interpretation, as mentioned above.

When searching for paper currency, the pattern of the alarm response can give vital clues. American paper currency is not uniformly ferromagnetic, but rather has discrete areas of ferromagnetic material, such as ink, and other areas which are not ferromagnetic. Interestingly, for many currencies, not all of the ink on a particular bill is ferromagnetic.

When scanned with the present invention, ferromagnetic paper currency typically produces one of two distinct signals, or a combination of these two signals: (1) a signal demonstrating periodicity, called herein the “bump/bump/bump” response, corresponding to neatly stacked bills; and, (2) a signal without periodicity, corresponding to currency placed willy-nilly and with random orientation within a package.

If bills are stacked in neat piles as is often done in a suitcase, as the scanning tool wand W is moved in close proximity to the surface of the suitcase, box or package, a “bump/bump/bump” type of signal response occurs, as illustrated schematically and graphically in FIG. 5. This signal can be heard by the operator on the audible display, or seen on the visual display in the form of a graph, for example. As the wand W moves relative to the package P, each “bump” response BR corresponds to a suspicious detected signal such as would emanate from a stack of paper currency C, which is followed by a no-signal response NSR of various dimensions. This NSR dimension can be very small, if stacks of bills are arranged closely together, or larger, if the stacks of bills are separated. This no-signal response is then followed by another detected “bump” response signal BR, as yet more movement occurs and more currency stacks are detected. These “bump/bump/bump” responses are somewhat akin to a car driving on railroad tracks. Also, with a very sensitive wand system, note the “mini-bump” responses MBR, illustrating that the currency is not uniformly ferromagnetic over its surface, but rather each bill has discrete areas of ferromagnetic ink, and then areas of no ferromagnetic ink. Only when currency is neatly stacked, with each bill in the stack having the same orientation, can predictable and repetitive “mini-bumps” be observed, however.

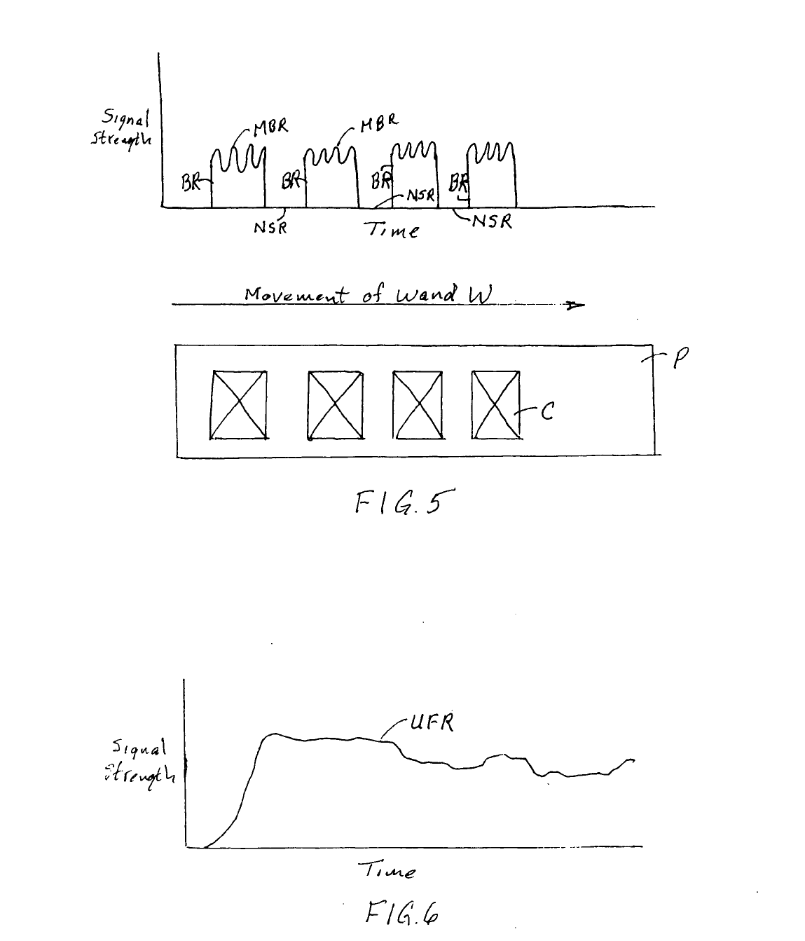

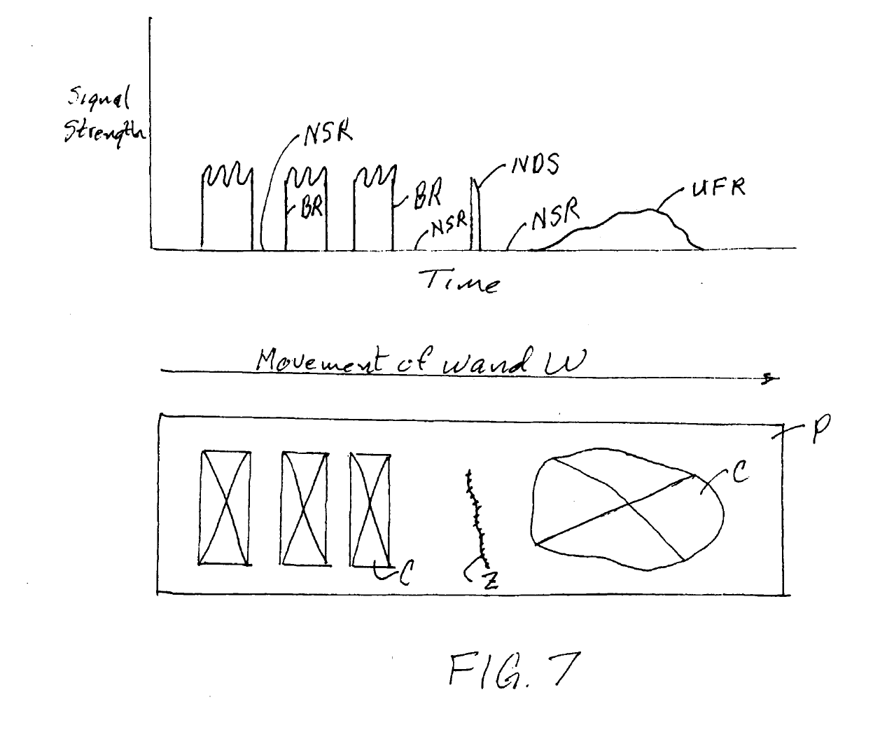

In the real-world, it is known that criminals often tend to stuff money into packages quite randomly, in which case there is no “bump/bump/bump” periodic response, but rather a fairly uniform signal response UFR which persists over an area, such as 6 to 16 inches across, as depicted in FIG. 6. This uniform but non-periodic signal UFR can be thought of as a “blurry” signal. If the package is larger, of course, either of these responses from paper currency can occur in patches, with a lack of signal elsewhere in the package, as shown in FIG. 7. Or, even “non-definitive signals” NDS, which arise from ferromagnetic objects which are other than paper currency, can be noted elsewhere in the package. Non-definitive signals NDS can be defined as small discrete signals which do not fit in one or the other of the two patterns typical of ferromagnetic paper currency. These NDS signals are very unlikely to be paper currency, but rather are usually caused by a small ferromagnetic object such as a zipper Z. Thus, the present invention provides discrimination between stacks of paper currency, either randomly placed or neatly stacked, producing a relatively broad signal response, and discrete ferromagnetic objects, such as zippers, producing a relatively short blip response.

Packages showing one of the two types of characteristic signal responses discussed above are very likely to contain ferromagnetic paper currency, especially as it is less common for a package to contain other ferromagnetic objects which exhibit either: (1) periodicity, and especially, predictable and repetitive periodicity; or, (2) a quite uniform ferromagnetic pattern over a fairly broad area, called herein a “blurry” pattern.

Even rolling bills into the smallest space possible produces a signal over a fairly broad area, assuming that the amount of currency is greater than a token. For example, $5,000 in 50 one-hundred dollar bills constitutes a roll having much more surface area than does a zipper. If a small, discrete ferromagnetic signal were found in one part of the package, and another at a distance of, for instance, 6 inches away, this does not correspond to a pattern consistent with concealed currency. Rather, this pattern is more representative of ferromagnetic objects of no interest, such as a zipper, or a piece of jewelry. Continued use of the present invention, augmented with automated pattern recognition with expert systems including neural nets, will result in more and more reliable detection of concealed paper currency in various forms.

The protective covering on the wand and the epoxy coating on the sensors not only provide insurance against damage, but also help to isolate the sensors from air currents and temperature changes which adversely affect sensitivity. The protective casing of the wand is preferably a non-ferromagnetic material, such as plastic or aluminum.

The preferred method of operation of the present invention is to screen all sides of the box or package, positioning the scanning tool wand as close to the surface of the box or package as possible. Proximity increases sensitivity, as the received signal from ferromagnetic paper currency is inversely proportional to the cube of the distance between the currency and the sensors. For example, doubling the distance results in decreasing the received signal strength to one eighth of its initial value. Two axis detection can be achieved by moving the wand to the left and to the right, relative to the operator, (nominally along an x axis) and away from the operator and toward the operator (nominally along a y axis). For all practical purposes, scanning in small circles accomplishes the same goal, i.e., detection along the x and y axes. Moving the wand toward and away from the surface of the package provides detection along the z axis. By scanning all sides of the package, three axis detection is ensured, and, if paper currency is closer to one side than to the others, detectability of this currency is greatly enhanced. This can be important, since it is typically unknown how close, or far away, the hidden currency is from the surface. For instance, a 1 inch box containing paper currency could be concealed within an 8 inch box. It should be noted that the present invention is incapable of reading mail, thereby maintaining privacy, a strict requirement of the United States Post Office.

While the particular invention as herein shown and disclosed in detail is fully capable of obtaining the objects and providing the advantages hereinbefore stated, it is to be understood that this disclosure is merely illustrative of the presently preferred embodiments of the invention and that no limitations are intended other than as described in the appended claims.

We claim:

1. A method for detecting ferromagnetic paper currency hidden within a package, comprising:
providing a scanning tool adapted for hand movement by an operator, said scanning tool including a DC magnetization source and at least one DC magnetic sensor;
moving said scanning tool by hand and directing said scanning tool into proximity with said package;
applying a first DC magnetic field to any contents of said package, said first DC magnetic field being generated by said magnetization source;
generating a second DC magnetic field in any ferromagnetic paper currency that may be present in said package, said second DC magnetic field being caused to emanate from said ferromagnetic paper currency by said application of said first DC magnetic field to said ferromagnetic paper currency;
sensing said second DC magnetic field with said at least one DC magnetic sensor and generating a signal representative of said second DC magnetic field; and
analyzing said signal to detect a characteristic signal pattern indicating the presence of said ferromagnetic paper currency.

2. The method recited in claim 1, wherein said detection of said characteristic signal pattern further comprises analyzing said signal to detect a uniform and repetitive periodicity of said signal, said uniform and repetitive signal periodicity indicating the presence of ferromagnetic paper currency arranged in a uniform pattern.

3. The method recited in claim 2, wherein said detection of said uniform and repetitive periodicity indicates the presence of ferromagnetic paper currency arranged in a plurality of uniform stacks.

4. The method recited in claim 1, wherein said detection of said characteristic signal pattern further comprises analyzing said signal to detect a uniform ferromagnetic pattern over a broad area of said package, without periodicity in said signal, said non-periodic uniform signal pattern indicating the presence of ferromagnetic paper currency arranged in a random fashion.

5. The method recited in claim 1, further comprising generating an alarm signal to indicate detection of said characteristic signal pattern indicating the presence of ferromagnetic paper currency.

6. The method recited in claim 1, wherein said directing of said scanning tool into proximity with said package further comprises positioning of said scanning tool in proximity with a plurality of sides of said package.

7. The method recited in claim 6, wherein said directing of said scanning tool into proximity with said package further comprises positioning of said scanning tool in proximity with all sides of said package.

8. The method recited in claim 1, wherein said analyzing of said signal comprises employing artificial intelligence to recognize said characteristic signal pattern.

9. The method recited in claim 1, further comprising transmitting data related to said signal via the Internet.

10. An apparatus for detecting ferromagnetic paper currency within a package, comprising:
a scanning tool;
a DC magnetization source on said scanning tool;
means for placing said scanning tool in proximity with a package, to thereby apply a first DC magnetic field to any contents of said package, said first DC magnetic field being generated by said magnetization source;
at least one DC magnetic sensor on said scanning tool, said DC magnetic sensor being adapted to sense a second DC magnetic field from any ferromagnetic paper currency that may be present in said package, said second DC magnetic field being caused to emanate from said ferromagnetic paper currency by said application of said first DC magnetic field to said ferromagnetic paper currency;
means for generating a signal representative of said second DC magnetic field; and
means for analyzing said signal to detect a characteristic signal pattern indicating the presence of ferromagnetic paper currency.

11. The apparatus recited in claim 10, wherein said means for analyzing said signal comprises means adapted to detect a uniform and repetitive periodicity of said signal, said uniform and repetitive signal periodicity indicating the presence of ferromagnetic paper currency arranged in a uniform pattern.

12. The apparatus recited in claim 10, wherein said means for analyzing said signal comprises means adapted to detect a uniform ferromagnetic pattern over a broad area of said package, without periodicity in said signal, said non-periodic uniform signal pattern indicating the presence of ferromagnetic paper currency arranged in a random fashion.

13. The apparatus recited in claim 10, further comprising an alarm adapted to generate a signal to indicate detection of said characteristic signal pattern.

14. The apparatus recited in claim 10, further comprising a handle mounted to said scanning tool.

15. The apparatus recited in claim 10, wherein said DC magnetic source comprises a permanent magnet.

16. The apparatus recited in claim 15, wherein said permanent magnet comprises a ceramic magnet.

17. The apparatus recited in claim 15, wherein said permanent magnet comprises a flexible rubber magnet.

18. The apparatus recited in claim 10, wherein said DC magnetic source comprises at least one DC electromagnetic coil.

19. The apparatus recited in claim 10, wherein said at least one DC magnetic sensor comprises at least two DC magnetic sensors arranged and connected as a gradiometer pair.
